(19) United States
(12) Patent Application Publication
(10) Pub. No.: US 2022/0230991 A1
(43) Pub. Date: Jul. 21, 2022

(54) MULTI-DIE PACKAGE STRUCTURE AND MULTI-DIE CO-PACKING METHOD

(71) Applicant: Monolithic Power Systems, Inc., San Jose, CA (US)

(72) Inventors: Hunt Jiang, Saratoga, CA (US); Deming Xiao, Los Altos Hills, CA (US)

(21) Appl. No.: 17/154,519

(22) Filed: Jan. 21, 2021

(51) Int. Cl. H01L 25/065; H01L 23/31; H01L 23/498; H01L 23/538; H01L 23/00; H01L 25/00; H01L 21/56

(52) U.S. Cl. CPC H01L 25/0652; H01L 23/3107; H01L 23/49827; H01L 2924/13091; H01L 24/13; H01L 25/50; H01L 21/565; H01L 23/5384

(57) ABSTRACT

A multi-die package structure with an embedded die embedded in a substrate, and a flip chip die mounted above the substrate is discussed. The package is compact and low cost.

### FIELD

The present invention relates to semiconductor packages, and more particularly relates to multi-die package structures.

### BACKGROUND

The requirements for customer electronics products have increased significantly in recent years. Miniaturization and portability are overwhelming trends which push the IC package to be more compact. Accordingly, the electronic portable devices become smaller and smaller along with more functions and better performances. Thus, today's power supply systems are required to have smaller size along with higher power output, more functions and better efficiency. Under these requirements, some technology incorporate switching devices such as FETs and controllers into a monolithic die. However, the controllers typically adopt CMOS process which may need 18-20 masks during fabrication, while the FETs typically adopt DMOS process which needs 8-9 masks during the fabrication. So such monolithic die costs a lot in order to fabricate the FETs together with the controller.

### SUMMARY

It is an object of the present invention to provide a solution, which solves the above problems.

In accomplishing the above and other objects, there has been provided, in accordance with an embodiment of the present invention, a multi-die package structure, comprising: an embedded die, configured to be embedded in a substrate; and a flip chip die, mounted above the substrate, the flip chip die having a first surface facing down to the substrate; wherein the first surface of the flip chip die is configured to contact with the embedded die and the substrate by way of a conductor.

In accomplishing the above and other objects, there has been provided, in accordance with an embodiment of the present invention, a multi-die co-packed chip, comprising: an control pin, configured to receive a control signal, the control pin electrically coupled to a controller die on which a control circuit is fabricated; an input pin, configured to receive an input voltage, the input pin electrically coupled to a first FET die on which a high side power switch is fabricated; a switch pin, electrically coupled to the first FET die and a second FET die on which a low side power switch is fabricated; and a ground pin, electrically coupled to the second FET die; wherein one die among the control die, the first FET die and the second FET die is embedded in a substrate as an embedded die, and the other two dies among the control die, the first FET die and the second FET die are mounted above the substrate as a first flip chip die and a second flip chip die.

In accomplishing the above and other objects, there has been provided, in accordance with an embodiment of the present invention, a multi-die co-packing method, comprising: embedding an embedded die in a substrate, the substrate having multiple metal layers; mounting a flip chip die over the substrate, with a top surface of the flip chip die facing down to the substrate; and molding the embedded die, the flip chip die and the substrate as a package.

### BRIEF DESCRIPTION OF THE DRAWINGS

FIG. 1 schematically shows a sectional view of a multi-die package structure 100 in accordance with an embodiment of the present invention.

FIG. 2 schematically shows a sectional view of a multi-die package structure 200 in accordance with an embodiment of the present invention.

FIG. 3 schematically shows a top plane view of a multi-die package structure 200 in FIG. 2 in accordance with an embodiment of the present invention.

FIG. 4 schematically shows a top plane view of a multi-die package structure 200 in FIG. 2 in accordance with another embodiment of the present invention.

FIG. 5 schematically shows a sectional view of a multi-die package structure 500 in accordance with an embodiment of the present invention.

FIG. 6 schematically shows a top plane view of a multi-die package structure 500 in FIG. 5 in accordance with an embodiment of the present invention.

FIG. 7 schematically shows a top plane view of a multi-die package structure 500 in FIG. 5 in accordance with another embodiment of the present invention.

FIG. 8 schematically shows a buck converter 800 in accordance with an embodiment of the present invention.

FIG. 9 schematically shows a top plane view of the multi-die package chip 900 in accordance with an embodiment of the present invention.

FIG. 10 schematically shows a flowchart 1000 of a multi-die co-packing method in accordance with an embodiment of the present invention.

The use of the similar reference label in different drawings indicates the same of like components.

### DETAILED DESCRIPTION

Embodiments of circuits for multi-die package structure incorporating embedded die and flip chip dies are described in detail herein. In the following description, some specific details, such as example circuits for these circuit components, are included to provide a thorough understanding of embodiments of the invention. One skilled in relevant art will recognize, however, that the invention can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

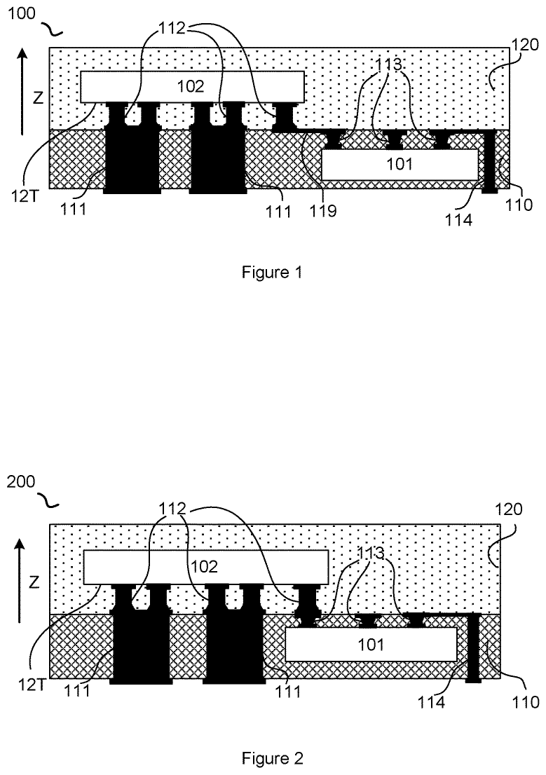

FIG. 1 schematically shows a sectional view of a multi-die package structure 100 in accordance with an embodiment of the present invention. In the example of FIG. 1, the multi-die package structure 100 comprises: an embedded die 101, configured to be embedded in a substrate 110; and a flip chip die 102, mounted above the substrate 110, the flip chip die 102 having a first surface 12T facing down to the substrate 110; wherein the first surface 12T of the flip chip die 102 is configured to contact with the embedded die 101 and the substrate 110 by way of a conductor.

In one embodiment of the present invention, integrated circuit/circuits and electric contact pads (e.g. contact bumps) are formed on the first surface of the dies. In one embodiment of the present invention, the first surface of a die is also called as a top surface; and the die also has a second surface opposite to the first surface, which is also called as a bottom surface.

One skilled in the art should realize that the term “flip chip die” in one embodiment may include any die that the contact area of the die directly connects with lead frame structure or package substrate by bump; the term “substrate” may refer to a package-level material similar as that used in a printed circuit board (PCB), which typically has multiple metal layers; and the term “contact bump” may refer to a small metal solid in a ball or pillar shape usually comprises the solder material used to directly connect two contact areas.

In one embodiment of the present invention, the conductor between the flip chip die 102 and the embedded die 101 includes a contact bump 112, a metal trace (e.g., copper trace) 119 and an electric contact (e.g., a laser via or a contact bump) 113; and the conductor between the flip chip die 102 and a bottom side of the substrate 110 includes the contact bump 112 and a through via 111. However, one skilled in the art should realize that the metal trace 119 between the flip chip die 102 and the embedded die 101 may be not needed, as will discussed below with reference to FIG. 2.

In one embodiment of the present invention, the multi-die package structure 100 further comprises: molding material 120, encapsulating and protecting the flip chip die 102, the substrate 110, and the contact bumps 112. In one embodiment of the present invention, molding material comprises a kind of electrical insulation material such as epoxy.

In one embodiment of the present invention, the electric contacts 113 act as an input and/or an output terminal of the embedded die 101, which may be lead out by way of a through via 114 from bottom side of the substrate 110.

FIG. 2 schematically shows a sectional view of a multi-die package structure 200 in accordance with an embodiment of the present invention. The multi-die package structure 200 in FIG. 2 is similar to the multi-die package structure 100 in FIG. 1, with a difference that in the example of FIG. 2, at least partial periphery of the embedded die 101 is overlapped with partial periphery of the flip chip die 102 in vertical direction (Z direction as shown in FIG. 2), so that the conductor between the flip chip die 102 and the embedded die 101 includes no metal trace, to have less parasitic resistances and shortest vertical contact bumps between the flip chip die 102 and the embedded die 101.

In one embodiment of the present invention, the vertical direction is a direction vertical to the die plane, i.e., vertical to the first surface and/or the second surface of the die. That is, the vertical direction is perpendicular with the dies 101 and 102.

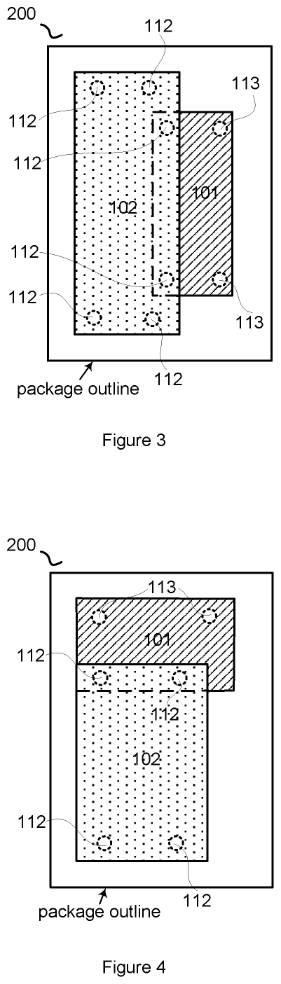

FIG. 3 schematically shows a top plane view of the multi-die package structure 200 in FIG. 2 in accordance with an embodiment of the present invention. FIG. 4 schematically shows a top plane view of the multi-die package structure 200 in FIG. 2 in accordance with another embodiment of the present invention. As shown in FIG. 3 and FIG. 4, the flip chip die 102 and the embedded die 101 are co-packed inside a package outline, and the embedded die 101 are partially overlapped (as shown with dashed lines) with the flip chip die 101.

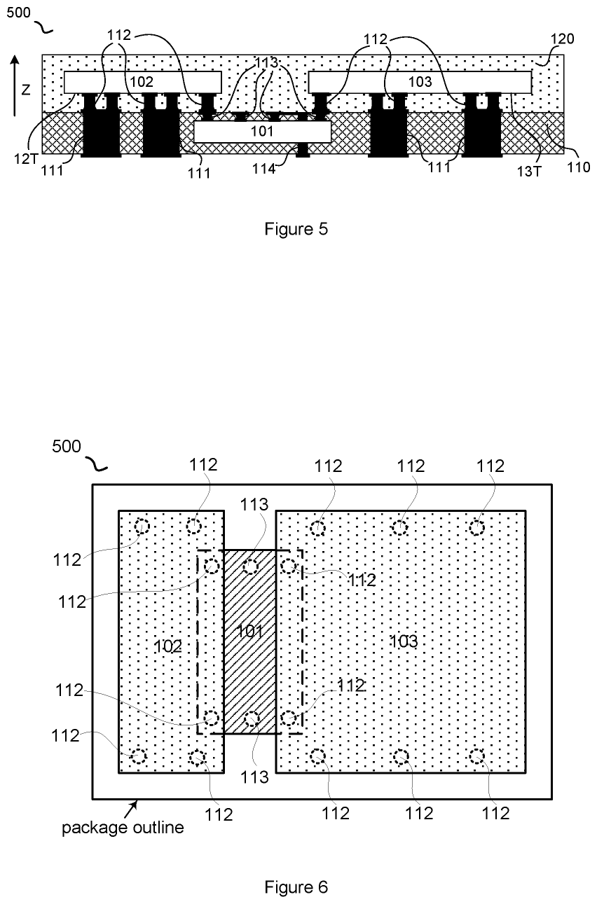

In one embodiment of the present invention, the multi-die package structure may comprise more than one flip chip die, e.g., the multi-die package structure may have two or more flip chip dies mounted over the substrate. As shown in FIG. 5, a multi-die package structure 500 having two flip chip dies is illustrated. Specifically, in the example of FIG. 5, the multi-die package structure 500 comprises: an embedded die 101, configured to be embedded in a substrate 110; a first flip chip die 102 and a second flip chip die 103, mounted above the substrate 110, the first flip chip die 102 and the second flip chip die 103 each having a first surface (12T, 13T) facing down to the substrate 110; wherein the first surface 12T of the first flip chip die 102 and the first surface 13T of the second flip chip die 103 are configured to contact with the first surface 11T of the embedded die 101 and the substrate 110 by way of a conductor, respectively.

In the embodiment of FIG. 5, the conductor between the first flip chip die 102 and the bottom side of the substrate 110, and the conductor between the second flip chip die 103 and the bottom side of the substrate 110 both include the contact bump 112 and the through via 111. The conductor between the first flip chip die 102 and the embedded die 101, and conductor between the second flip chip die 103 and the embedded die 101 both include the contact bump 112 and the electric contact 113 as that in FIG. 2, and no metal trace is included. However, one skilled in the art should realize that in other embodiments of the present invention, the metal trace may be included to formed the conductor, as that in FIG. 1.

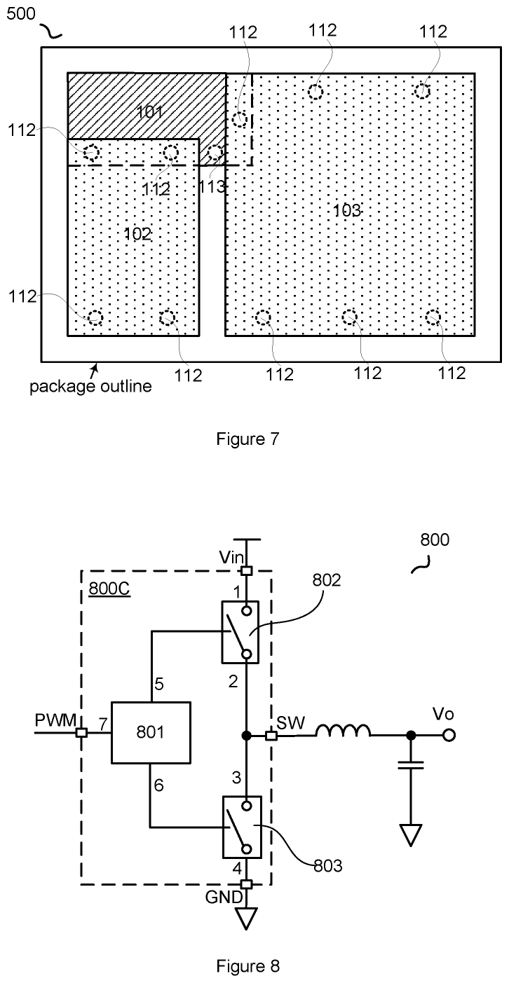

That is, in the embodiment of FIG. 5, partial periphery of the embedded die 101 is overlapped with partial periphery of the first flip chip die 102 in vertical direction (Z direction as shown in FIG. 5); and partial periphery of the embedded die 101 is also overlapped with partial periphery of the second flip chip die 103 in vertical direction, so that the conductor between the flip chip die 102 and the embedded die 101 and the conductor between the second chip die 103 and the embedded die 101 both include no metal trace, so as to have less parasitic resistances and shortest vertical contact bumps between the first flip chip die 102, the second flip chip die 103 and the embedded die 101. As shown in FIG. 6 and FIG. 7.

In one embodiment, the vertical direction is a direction vertical to the die plane, i.e., vertical to the first surface and/or the second surface of the die. That is, the vertical direction is perpendicular with the dies 101, 102 & 103.

FIG. 6 schematically shows a top plane view of a multi-die package structure 500 in FIG. 5 in accordance with an embodiment of the present invention. FIG. 7 schematically shows a top plane view of a multi-die package structure 500 in FIG. 5 in accordance with another embodiment of the present invention. As shown in FIG. 6 and FIG. 7, the embedded die 101, the first flip chip die 102 and the second flip chip die 103 are co-packed inside a package outline, and the embedded die 101 are partially overlapped (as shown with dashed lines) with the first flip chip die 102 and the second flip chip die 103.

In one embodiment, the embedded die 101 and the flip chip die (e.g., the first flip chip die 102 and/or the second flip chip die 103) may comprise switch power devices and a controller operable to control the switch power devices. For example, the embedded die 101 may comprise a switch power device, and the flip chip die may comprise the corresponding controller; or the flip chip die may comprise a switch power device, and the flip chip die may comprise the corresponding controller. In a specific embodiment, the first flip chip die 102 may comprise a high side FET in a buck converter, the second flip chip die 103 may comprise a low side FET in the buck converter, and the embedded die 101 may comprise a controller operable to control the two FETs. The buck converter may be adopted in a multi-phase DC-DC conversion system. However, one skilled in the art should realize that the embedded die and the flip chip die may comprise other semiconductor devices in other embodiments of the present invention.

FIG. 8 schematically shows a buck converter 800 in accordance with an embodiment of the present invention. In the example of FIG. 8, the buck converter 800 comprises: a multiple-die co-packed chip 800C including: an control pin PWM, configured to receive a control signal (e.g. from a pre-stage), the control pin PWM electrically coupled to a controller die 801 on which a control circuit is fabricated; an input pin Vin, configured to receive an input voltage, the input pin Vin electrically coupled to a first FET die 802 on which a high side power switch is fabricated; a switch pin SW, electrically coupled to the first FET die 802 and a second FET die 803 on which a low side power switch is fabricated; and a ground pin GND, electrically coupled to the second FET die 803, wherein one die among the control die, the first FET die and the second FET die is embedded in a substrate as an embedded die, and other two dies among the control die, the first FET die and the second FET die are mounted above the substrate as a first flip chip die and a second flip chip die.

In one embodiment, the high side power switch and the low side power switch are controlled by the control circuit.

In one embodiment of the present invention, partial periphery of the embedded die is overlapped with partial periphery of the first flip chip die and partial periphery of the second flip chip die in vertical direction.

Continue referring to FIG. 8, the first FET die 802 having a first terminal 1 electrically coupled to the input pin Vin, a second terminal 2 electrically coupled to the switch pin SW, and a control terminal electrically coupled to the controller die 801. The second FET die 803 having a first terminal 3 electrically coupled to the switch pin SW, a second terminal 4 electrically coupled to the ground pin GND, and a control terminal electrically coupled to the controller die 801. The controller die 801 having an input terminal 7 electrically coupled to the control pin PWM, a first output terminal 5 electrically coupled to the control terminal of the first FET die 801, and a second output terminal 6 electrically coupled to the control terminal of the second FET die 803.

In one embodiment, the buck converter 800 further comprises an inductor and an output capacitor, both coupled to the switch pin SW of the multi-die package chip 800C.

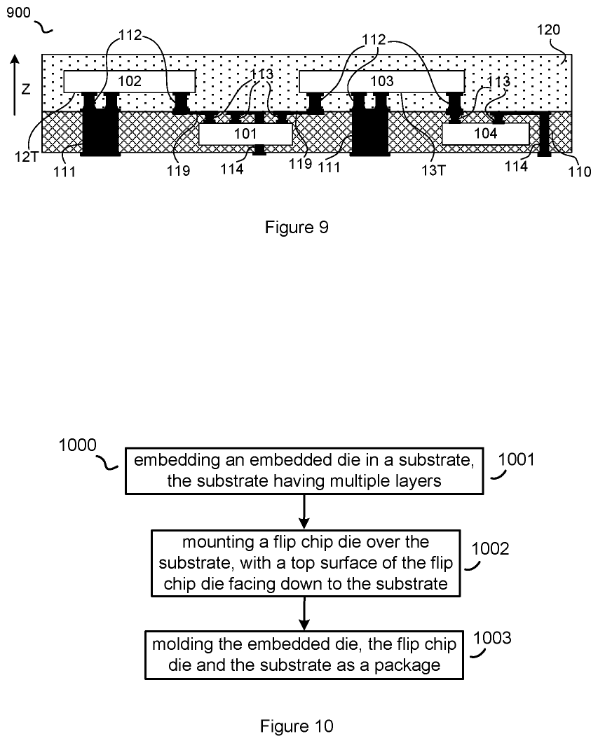

Several embodiments of the foregoing multi-die package structure discuss one embedded die with one or more (e.g. two) flip chip dies co-packed in one package outline. However, in other embodiments of the present invention, the multi-die package structure may comprise more than one embedded die with one or more flip chip dies co-packed in one package outline. That is, in one embodiment of the present invention, the multi-die package structure may comprise any desired number of embedded die and any desired number of flip chip die co-packed in one package outline. As shown in FIG. 9, a multi-die package structure 900 having two embedded dies and two flip chip dies is illustrated.

Specifically, in the example of FIG. 9, the multi-die package structure 900 comprises: a first embedded die 101 and a second embedded die 104, configured to be embedded in a substrate 110; and a first flip chip die 102 and a second flip chip die 103, mounted above the substrate 110, the first flip chip die 102 and the second flip chip die 103 each having a first surface (12T, 13T) facing down to the substrate 110; wherein the first surface 12T of the first flip chip die 102 is configured to contact with the first embedded die 101 and the substrate 110 by way of conductors; and the first surface 13T of the second flip chip die 103 is also configured to contact with the first embedded die 101, the second embedded die 104, and the substrate 110 by way of conductors.

In the embodiment of FIG. 9, the conductor between the first flip chip die 102 and the first embedded die 101, and the conductor between the second flip chip die 103 and the first embedded die 101 include a contact bump 112, a metal trace 119 and an electric contact (e.g., a laser via or a contact bump) 113; and the conductor between the second flip chip die 103 and the second embedded die 104 only includes the contact bump 112 and electric contact 113. That is, the first embedded die 101 is shifted from (i.e. has no overlapped with) the first flip chip die 102 and the second flip chip die 103 in vertical direction, but partial periphery of the second embedded die 104 is overlapped with partial periphery of the second flip chip die 103. However, one skilled in the art should realize that, in other embodiments of the present invention, partial periphery of the first embedded die 101 may be overlapped with partial periphery of the first flip chip die 102 and partial periphery of the second flip chip die 103 in vertical direction, and the second embedded die 104 may be shifted from the second flip chip die 103 in vertical direction.

Several embodiments of the foregoing multi-die package structure provide much compact solution for smaller package size and less parasitic RLC (resistance, inductance and capacitance), which brings better performance. Unlike the conventional technique, several embodiments of the foregoing multi-die package structure may adopt different process to fabricate different dies (e.g., the flip chip die with one process and the embedded die with another process), and then co-pack the dies together with some of the dies embedded in the substrate, and the other dies mounted above the substrate and contacting with the embedded dies and with the substrate through contact bumps. Thus the total cost is down. In addition, the embedded die is overlapped with the flip chip die partially in a direction vertical to the die plane, resulting a smaller package size, which further saves the cost.

FIG. 10 schematically shows a flowchart 1000 of a multi-die co-packing method in accordance with an embodiment of the present invention. The method comprising:

Step 1001, embedding an embedded die in a substrate, the substrate having multiple metal layers.

Step 1002, mounting a flip chip die over the substrate, with a top surface of the flip chip die facing down to the substrate. And

Step 1003, molding the embedded die, the flip chip die and the substrate as a package.

In one embodiment of the present invention, at least partial periphery of the embedded die is overlapped with partial periphery of the flip chip die in vertical direction perpendicular with the embedded die.

In one embodiment of the present invention, the embedded die is shifted from the flip chip die in vertical direction perpendicular with the embedded die.

It is to be understood in these letters patent that the meaning of “A” is coupled to “B” is that either A and B are connected to each other as described below, or that, although A and B may not be connected to each other as described above, there is nevertheless a device or circuit that is connected to both A and B. This device or circuit may include active or passive circuit elements, where the passive circuit elements may be distributed or lumped-parameter in nature. For example, A may be connected to a circuit element that in turn is connected to B.

This written description uses examples to disclose the invention, including the best mode, and also to enable a person skilled in the art to make and use the invention. The patentable scope of the invention may include other examples that occur to those skilled in the art.

1. A multi-die package structure, comprising:
an embedded die, configured to be embedded in a substrate, the embedded die having a plurality of integrated circuits formed thereon; and
a flip chip die, mounted above the substrate, the flip chip die having a first surface facing down to the substrate; wherein the first surface of the flip chip die is configured to contact with the embedded die by way of a first conductor, and contact with the substrate by way of a second conductor.

2. The multi-die package structure of claim 1, wherein:
the first conductor between the flip chip die and the embedded die includes a first contact bump, a metal trace and an electric contact; and
the second conductor between the flip chip die and a bottom side of the substrate includes a second contact bump and a through via.

3. The multi-die package structure of claim 1, wherein at least partial periphery of the embedded die is overlapped with partial periphery of the flip chip die in vertical direction.

4. The multi-die package structure of claim 1, wherein the flip chip die is a first flip chip die, the multi-die package structure further comprising:
a second flip chip die, mounted above the substrate, the second flip chip die having a first surface facing down to the substrate; wherein the first surface of the second flip chip die is configured to contact with the embedded die and the substrate.

5. The multi-die package structure of claim 4, wherein:
partial periphery of the embedded die is overlapped with partial periphery of the first flip chip die in vertical direction; and
partial periphery of the embedded die is overlapped with partial periphery of the second flip chip die in vertical direction.

6. The multi-die package structure of claim 4, wherein the embedded die is a first embedded die, the multi-die package structure further comprising:
a second embedded die, configured to be embedded in the substrate; wherein the first surface of the second flip chip die is further configured to contact with the second embedded die.

7. A multi-die co-packed chip, comprising:
a control pin, configured to receive a control signal, the control pin electrically coupled to a controller die on which a control circuit is fabricated;
an input pin, configured to receive an input voltage, the input pin electrically coupled to a first FET die on which a high side power switch is fabricated;
a switch pin, electrically coupled to the first FET die and a second FET die on which a low side power switch is fabricated; and
a ground pin, electrically coupled to the second FET die; wherein:
one die among the control die, the first FET die and the second FET die is embedded in a substrate as an embedded die, and the other two dies among the control die, the first FET die and the second FET die are mounted above the substrate as a first flip chip die and a second flip chip die.

8. The multi-die co-packed chip of claim 7, wherein:
partial periphery of the embedded die is overlapped with partial periphery of the first flip chip die and partial periphery of the second flip chip die in vertical direction.

9. A multi-die co-packing method, comprising:
embedding an embedded die in a substrate, the substrate having multiple metal layers;
mounting a flip chip die over the substrate, with a top surface of the flip chip die facing down to the substrate; and
molding the embedded die, the flip chip die and the substrate as a package.

10. The multi-die co-packing method of claim 9, wherein:
at least partial periphery of the embedded die is overlapped with partial periphery of the flip chip die in vertical direction perpendicular with the embedded die.

11. The multi-die co-packing method of claim 9, wherein:
the embedded die is shifted from the flip chip die in vertical direction perpendicular with the embedded die.
